(19) United States
(12) Patent Application Publication
(10) Pub. No.: US 2009/0115065 A1
(43) Pub. Date: May 7, 2009

(54) SEMICONDUCTOR DEVICE AND MANUFACTURING METHOD THEREOF

(76) Inventor: Cheon-Man Shim, Yeongdeungpo-gu (KR)

Correspondence Address: SHERR & VAUGHN, PLLC, 620 HERNDON PARKWAY, SUITE 200, HERNDON, VA, 20170, US

(21) Appl. No.: 12/248,144

(22) Filed: Oct. 9, 2008

(30) Foreign Application Priority Data
Nov. 6, 2007 (KR) 10-2007-0112543

(51) Int. Cl. H01L 23/48; H01L 21/4763

(52) U.S. Cl. 257/773; 438/618; 257/E21.209

(57) ABSTRACT

Embodiments relate to a semiconductor device that may include a semiconductor substrate including a cell area and a pad area, a first insulating layer on and/or over the semiconductor substrate, and a first interconnection trench formed in the first insulating layer on and/or over a cell area having a first width. It may also include a first pad trench formed in the first insulating layer on and/or over the pad area and having a second width wider than the first width, and a first metal interconnection formed in the first interconnection trench and a first pad formed in the first pad trench. It may further include a second insulating layer on and/or over the first insulating layer, a second interconnection trench, exposing the first metal interconnection, and a second pad exposing the first pad and having a position and width substantially identical to that of the first pad trench.

The present application claims priority under 35 U.S.C. 119 to Korean Patent Application No. 10-2007-0112543 (filed on Nov. 6, 2007), which is hereby incorporated by reference in its entirety.

### BACKGROUND

An internal logic area of a semiconductor device may be electrically connected with an external system. A pad may be formed to electrically connect a logic area with an external system.

Semiconductor devices have become highly integrated and may operate at high speeds. In addition, transistor sizes have become smaller. As the degree of integration of a transistor increases, a metal line of a semiconductor device may be fabricated in a micro size. As a result, signals applied to the metal line may be delayed or distorted. Thus a high-speed operation of a semiconductor device may be interrupted. To reduce resistance of a metal line, low-k material (k>3.0) having a low dielectric constant may be used as an interlayer dielectric layer of the metal line.

Further, after a pad of a semiconductor device is formed together with a metal line, the pad may be connected with an external system through wire bonding. However, since low-k material may have a low strength as compared with other types of insulating layers, peeling and cracking may occur in the pad due to pressure when the pad is subjected to the wire bonding.

### SUMMARY

Embodiments relate to a semiconductor device and a method of manufacturing a semiconductor device. Embodiments may also relate to a semiconductor device capable of reinforcing a strength of a pad area, and a method of manufacturing the same.

According to embodiments, a device may include at least one of the following elements. A semiconductor substrate including a cell area and a pad area. A first insulating layer on and/or over the semiconductor substrate. A first interconnection trench formed in the first insulating layer on and/or over cell area and having a first width. A first pad trench formed in the first insulating layer on and/or over the pad area and having a second width wider than the first width. A first metal interconnection formed in the first interconnection trench and a first pad formed in the first pad trench. A second insulating layer on and/or over the first insulating layer. A second interconnection trench formed in the second insulating layer to expose the first metal interconnection. A second pad trench on and/or over the second insulating layer such that the second pad trench exposes the first pad and has position and width substantially identical to that of the first pad trench. A second metal interconnection formed in the second interconnection trench and a second pad formed in the second pad trench.

According to embodiments, a method for manufacturing a semiconductor device may include at least one of the following. Forming a first insulating layer on and/or over a semiconductor substrate including a cell area and a pad area. Forming a first interconnection trench having a first width in the first insulating layer on and/or over the cell area. Forming a first pad trench in the first insulating layer on and/or over the pad area, the first pad trench having a second Width wider than the first width. Forming a second insulating layer on and/or over the first insulating layer. Forming a second interconnection trench in the second insulating layer to expose the first metal interconnection. Forming a second pad trench on and/or over the second insulating layer such that the second pad trench exposes the first pad and has position and width substantially identical to that of the first pad trench. Forming a second metal interconnection in the second interconnection trench and forming a second pad in the second pad trench.

### DRAWINGS

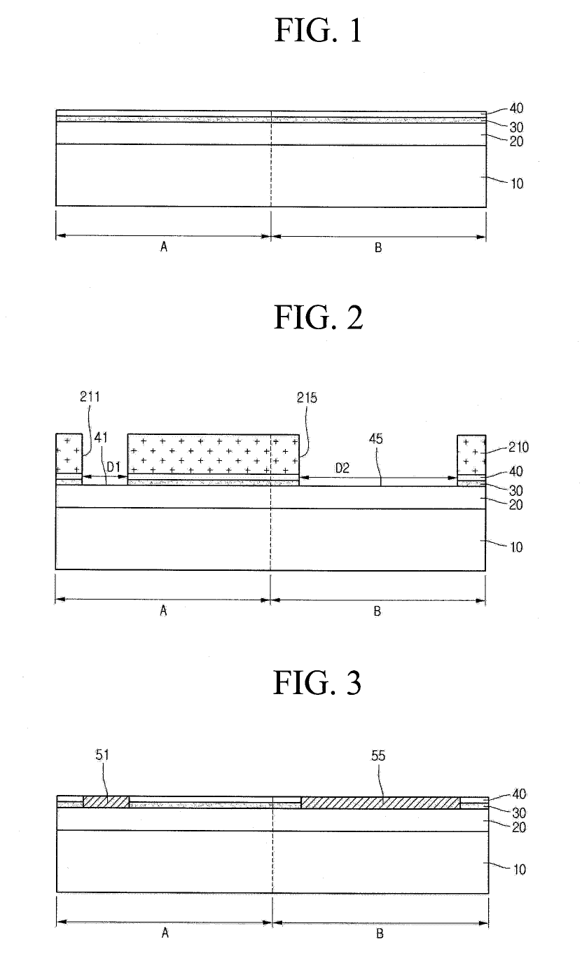

Example FIGS. 1 to 11 are sectional views illustrating a semiconductor device and a method of manufacturing a semiconductor device, according to embodiments.

### DESCRIPTION

Example FIG. 11 is a sectional view illustrating a semiconductor device according to embodiments. Referring to example FIG. 11, a first insulating layer may be disposed on and/or over semiconductor substrate 10 including a cell area A and a pad area B. According to embodiments, semiconductor substrate 10 may include an isolation area and a transistor circuit. Pre-metal dielectric (PMD) layer 20, which may include a contact, may be provided on and/or over semiconductor substrate 10. PMD layer 20 may be an insulating layer and may be prepared in the form of a un-doped silicate (USG) layer. PMD layer 20 may also include at least one of MSQ (methyl silsesquioxane), HSQ (Hydrogen silsesquioxane), FSQ (Fluorine-doped silicate), and CDO (carbon doped oxide), which may have hard properties from among low-k materials. The first insulating layer may include first interconnection trench 41 and first pad trench 45. According to embodiments, first insulating layer may be formed by stacking first low dielectric layer 30 and first oxide layer 40.

First metal interconnection 51 may be disposed in first interconnection trench 41. First pad 55 may be disposed in first pad trench 45. According to embodiments, first interconnection trench 41 may have a first width D1 and first pad trench 45 may have a second width D2, which may be larger than the first width D1. First metal interconnection 51 and first pad 55 may include conductive material. According to embodiments, first metal interconnection 51 and first pad 55 may include copper. According to embodiments, first barrier layer 60 may be disposed on and/or over the first insulating layer and may prevent the copper of first metal interconnection 51 and first pad 55 from being diffused to the insulating layer.

According to embodiments, a second insulating layer, which may include second interconnection trench 82 and second pad trench 85, may be disposed on and/or over first barrier layer 60. According to embodiments, the second insulating layer may be formed by stacking second low dielectric layer 70 and second oxide layer 80. Second interconnection trench 82 may be prepared in a form of a via trench, and may selectively expose first metal interconnection 51. According to embodiments, second pad trench 85 may have substantially a same position and width as a position and width of first pad trench 45, and this may expose first pad 55. According to embodiments, second metal interconnection 91 may be disposed in second interconnection trench 82 and second pad 95 may be disposed in second pad trench 85. Second metal interconnection 91 and second pad 95 may include conductive material, according to embodiments. For example, second metal interconnection 91 and second pad 95 may include copper.

According to embodiments, second barrier layer 100 may be disposed on and/or over the second insulating layer, and may prevent the copper of second metal interconnection 91 and second pad 95 from being diffused to the insulating layer. A third insulating layer, which may include second via hole 121 and third pad trench 125, may be disposed on and/or over second barrier layer 100. According to embodiments, second via hole 121 may selectively expose second metal interconnection 91. Third pad trench 125 may have substantially a same position and width as a position and width of second pad trench 85, and may expose second pad 95.

According to embodiments, via contact 131 may be disposed in second via hole 121. Third pad 135 may be disposed in third pad trench 125. Via contact 131 and third pad 135 may include conductive material. According to embodiments, via contact 131 and third pad 135 may include copper. Third metal interconnection 141 may be disposed on and/or over via contact 131 and upper pad 145 may be disposed on and/or over third pad 135. According to embodiments, first and second low dielectric layers 30 and 70 of the first and second insulating layers may include low-k material (K<3.0) and may have a lower dielectric constant such as at least one of SiOC:H, HSQ, MSQ, and P-MSQ. According to embodiments, the low dielectric layer having a lower dielectric constant may be used as an interlayer insulating layer of the copper metal interconnection. Hence, an RC delay may be minimized and a degree of integration and speed of a semiconductor device may be maximized.

According to embodiments, first, second, and third pads 55, 95, 135 may be formed below the upper pad. Hence, cracking and peeling may be minimized or prevented by distributing pressure during wire boding of the upper pad. According to embodiments, the first, second, and third pads 55, 95, 135 may support the lower area of the upper pad. This may minimize or eliminate problems that may otherwise occur during wire boding of the upper pad 145. According to embodiments, first, second, and third pads 55, 95, 135 may have a wide area in the pad area as compared with upper pad 145. Hence, a low dielectric layer having a low hardness may be removed. Thus, problems may not occur during wire boding.

Hereinafter, a semiconductor device and a method of manufacturing a semiconductor device according to embodiments will be described with reference to FIGS. 1 to 11.

Referring to example FIG. 1, a first insulating layer may be formed on and/or over semiconductor substrate 10, which may include cell area A and pad area B. According to embodiments, semiconductor substrate 10 may include an isolation area and a transistor circuit. Further, PMD layer 20, which may include a contact, may be formed on and/or over semiconductor substrate 10 such that PMD layer 20 may be connected with the transistor circuit. PMD layer 20 may include an oxide layer or a nitride layer. According to embodiments, PMD layer 20 may be prepared in the form of a USG layer. Further, PMD layer 20 may include at least one of MSQ, HSQ, FSQ, and CDO, which may have hard properties from among the low-k materials. According to embodiments, the first insulating layer may be formed on and/or over semiconductor substrate 10, including PMD layer 20. The first insulating layer may include first low dielectric layer 30 and first oxide layer 40. According to embodiments, first low dielectric layer 30 may include a low-k material (K<3.0), which may have a lower dielectric constant such as at least one of SiOC:H, HSQ, MSQ, and P-MSQ.

Referring to example FIG. 2, first interconnection trench 41 and first pad trench 45 may be formed in the first insulating layer. First interconnection trench 41 may expose PMD layer 20 of cell area A and first pad trench 45 may expose PMD layer 20 of pad area B. According to embodiments, to form first interconnection trench 41 and first pad trench 45, first photoresist pattern 210 may be formed on and/or over the first insulating layer. First photoresist pattern 210 may have first interconnection hole 211 and first pad hole 215, which may selectively expose PMD layer 20 of cell area A and pad area B. First pad hole 215 may have a width larger than a width of first interconnection hole 211. According to embodiments, the first insulating layer may be etched by using first photoresist pattern 210 as an etch mask, so that first interconnection trench 41 may be formed in cell area A, and first pad trench 45 may be formed in pad area B. According to embodiments, first interconnection trench 41 may have first width D1 to form a metal interconnection. Further, first pad trench 45 may have second width D2, which may be larger than first width D1. First photoresist pattern 210 may be removed, for example through a general ashing process.

Referring to example FIG. 3, first metal interconnection 51 may be formed in first interconnection trench 41 and first pad 55 may be formed in first pad trench 45. According to embodiments, first metal interconnection 51 and first pad 55 may be formed at substantially the same time. According to embodiments, a metal layer may be deposited on and/or over the first insulating layer, including first interconnection trench 41 and first pad trench 45, and may be subjected to a planarization process. Hence, first metal interconnection 51 may be formed in first interconnection trench 41 and first pad 55 may be formed in first pad trench 45. First metal interconnection 51 and first pad 55 may be formed with metal material having conductivity. According to embodiments, first metal interconnection 51 and first pad 55 may include at least one of Cu, Al, Ti, TiN, Ta, Tan, and TiSiN. According to embodiments, first metal interconnection 51 and first pad 55 may include copper. According to embodiments, before forming first metal interconnection 51 and first pad 55, a barrier metal layer and a seed layer may be formed in first interconnection trench 41 and first pad trench 45.

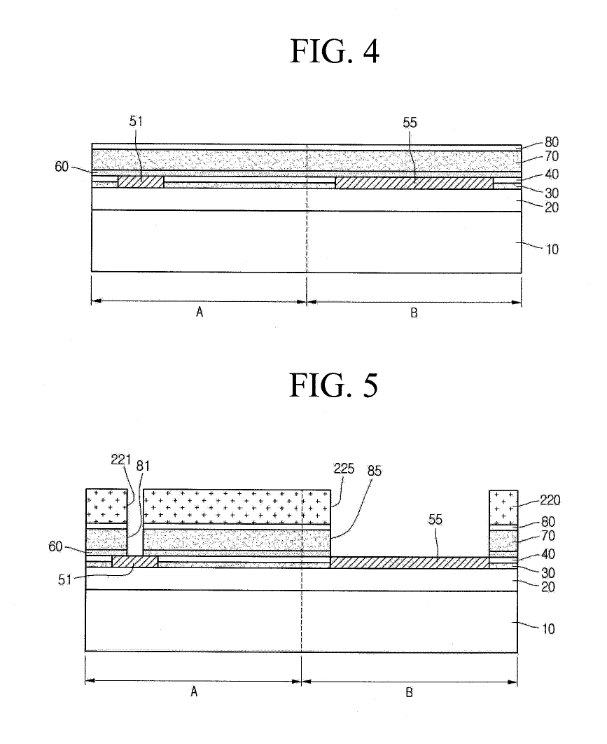

Referring to example FIG. 4, first barrier layer 60 may be formed on and/or over semiconductor substrate 10, which may include first metal interconnection 51 and first pad 55. According to embodiments, first barrier layer 60 may prevent copper of first metal interconnection 51 and first pad 55 from being diffused to the insulating layer. According to embodiments, first barrier layer 60 may include SiCN. Next, the second insulating layer may be formed on and/or over first barrier layer 60. The second insulating layer may include second low dielectric layer 70 and second oxide layer 80. According to embodiments, second low dielectric layer 70 may include a low-k material (K<3.0), which may have a lower dielectric constant such as at least one of SiOC:H, HSQ, MSQ, and P-MSQ.

Referring to example FIG. 5, first via hole 81 and second pad trench 85 may be formed in the second insulating layer. According to embodiments, first via hole 81 may selectively expose a surface of first metal interconnection 51 and second pad trench 85 may expose first pad 55. To form first via hole 81 and second pad trench 85, second photoresist pattern 220 may be formed on and/or over the second insulating layer. Second photoresist pattern 220 may include second interconnection hole 221 and second pad hole 225. According to embodiments, second pad hole 225 may have substantially a same position and size as a position and size of first pad hole 215. Second interconnection hole 221 of second photoresist pattern 220 may partially expose a surface of the second insulating layer corresponding to first metal interconnection 51. Further, second pad hole 225 may expose the second insulating layer corresponding to first pad 55. According to embodiments, the second insulating layer may be etched, for example using second photoresist pattern 220 as an etch mask, and may form first via hole 81 and second pad trench 85 in the second insulating layer. First via hole 81 may selectively expose a surface of first metal interconnection 51 and second pad trench 85 may expose first pad 55. According to embodiments, second pad trench 85 may have a same width as that of first pad trench 45. Second photoresist pattern 220 may be removed, for example through a general ashing process.

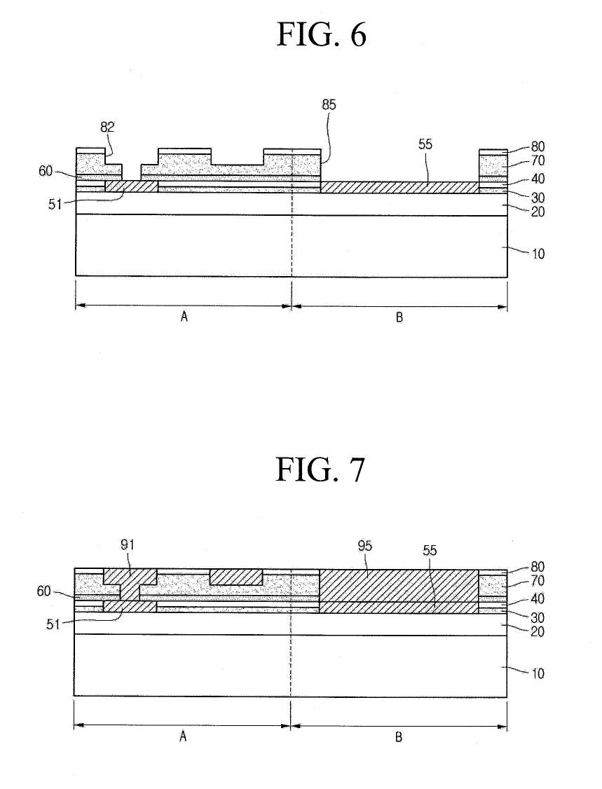

Referring to example FIG. 6, second interconnection trench 82, which may include first via hole 81, may be formed in the second insulating layer. Second interconnection trench 82 may be connected with first via hole 81 through a dual damascene process. According to embodiments, second interconnection trench 82 may be formed by forming a photoresist pattern, which may have a width larger than a width of first via hole 81, on and/or over the second insulating layer above first via hole 81. The second insulating layer may then be etched using the photoresist pattern as a mask. A via trench-type second interconnection trench 82 may be formed in first metal interconnection 51, and second pad trench 85 may be formed in first pad 55.

Referring to example FIG. 7, second metal interconnection 91 may be formed in second interconnection trench 82 and second pad 95 may be formed in second pad trench 85. According to embodiments, second metal interconnection 91 and second pad 95 may be formed using the same material and forming method as used to form first metal interconnection 51 and first pad 55. According to embodiments, a metal layer may be deposited on and/or over the second insulating layer, which may include second interconnection trench 82 and second pad trench 85. A planarization process may then be performed, so that second metal interconnection 91 may be formed in second interconnection trench 82 and second pad 95 may be formed in second pad trench 85. According to embodiments, second metal interconnection 91 and second pad 95 may include copper. According to embodiments, the second insulating layer, which may include second metal interconnection 91 and second pad 95, may not be formed.

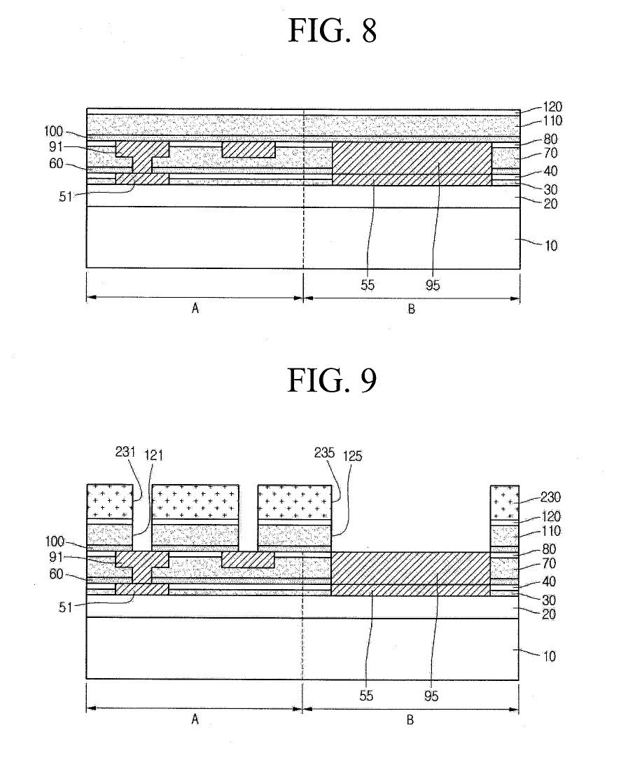

Referring to example FIG. 8, second barrier layer 100 may be formed on and/or over semiconductor substrate 10, including second metal interconnection 91 and second pad 95. Second barrier layer 100 may prevent the copper of second metal interconnection 91 and second pad 95 from being diffused to the insulating layer. According to embodiments, second barrier layer 100 may include SiCN. The third insulating layer may then be formed on and/or over second barrier layer 100. The third insulating layer may include third low dielectric layer 110 and third oxide layer 120. According to embodiments, third low dielectric layer 110 may include a low-k material (K<3.0), which may have a lower dielectric constant such as at least one of SiOC:H, HSQ, MSQ, and P-MSQ.

Referring to example FIG. 9, second via hole 121 and third pad trench 125 may be formed in the third insulating layer. Second via hole 121 may selectively expose a surface of second metal interconnection 91 and third pad trench 125 may expose second pad 95. According to embodiments, to form second via hole 121 and third pad trench 125, third photoresist pattern 230 may be formed on and/or over the third insulating layer. Third photoresist pattern 230 may include third interconnection hole 231 and third pad hole 235. According to embodiments, third pad hole 235 may be formed with substantially a same size as that of second pad hole 225. Third interconnection hole 231 of third photoresist pattern 230 may selectively expose a surface of the third insulating layer corresponding to second metal interconnection 91. Further, third pad hole 235 may expose the third insulating layer corresponding to second pad 95. According to embodiments, the third insulating layer may be etched, for example by using third photoresist pattern 230 as an etch mask, to form second via hole 121 and third pad trench 125 in the third insulating layer. Second via hole 121 may selectively expose a surface of third metal interconnection 91 and third pad trench 125 may expose third pad 95. Third pad trench 125 may have substantially a same position and width as a position and width of second pad trench 85. Third photoresist pattern 230 may then be removed, for example through a general ashing process.

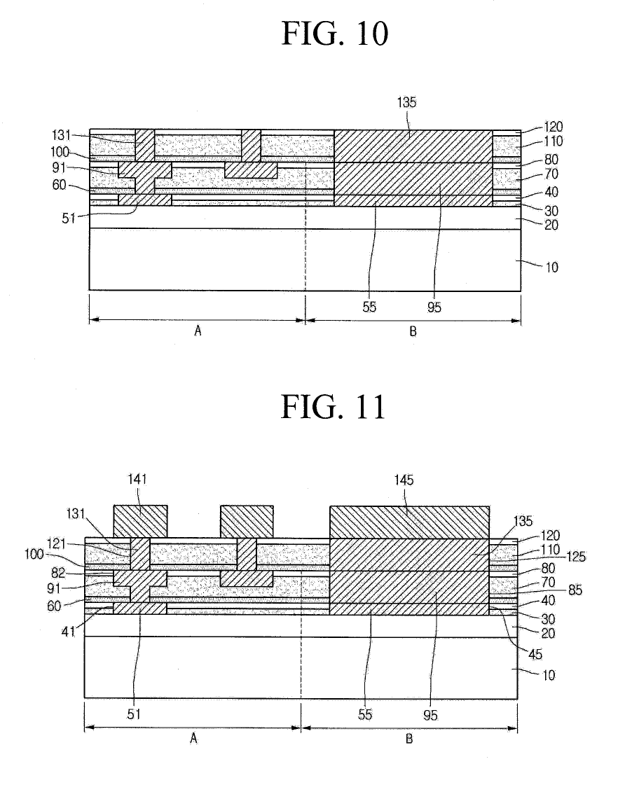

Referring to example FIG. 10, via contact 131 may be formed in second via hole 121 and third pad 135 may be formed in third pad trench 125. According to embodiments, via contact 131 and third pad 135 may be formed using substantially the same method as that for forming first metal interconnection 51 and first pad 55.

Referring to example FIG. 11, third metal interconnection 141 may be formed on and/or over via contact 131 and upper pad 145 may be formed on and/or over third pad 135. According to embodiments, third metal interconnection 141 and upper pad 145 may be formed at substantially the same time. According to embodiments, a metal layer may be formed on and/or over the third insulating layer including via contact 131 and third pad 135. It may then be patterned to form third metal interconnection 141 connected with via contact 131 and upper pad 145 connected with third pad 135. According to embodiments, third metal interconnection 141 and upper pad 145 may include aluminum. Upper pad 145 may then be electrically connected with an external system, for example through aluminum or metal wire bonding. According to embodiments, the first, second, and third insulating layers may be formed with a low dielectric layer and an oxide layer and the first and second metal interconnections 51, 91 may include copper. Hence, RC delay may be minimized. Accordingly, a degree of integration and a speed of a semiconductor may be improved.

According to embodiments, when forming first, second, and third metal interconnections 51, 91, 141, a lower pad including first, second, and third pads 55, 95, 135 and upper pad 145 may be formed in a pad area. For example, first, second, and third pads 55, 95, 135 may not be formed with the same pattern as that of the metal interconnection. According to embodiments, since first, second, and third pads 55, 95, 135 may be formed by forming a trench having a width larger than that of a metal interconnection, and filling copper material having a high hardness in the trench, a low dielectric layer having a low hardness may be removed. Thus, a lower pad having a high hardness may be formed below upper pad 145 and may have a wide area. This may minimize cracking and peeling by distributing pressure to the lower pad during the wire bonding of the upper pad.

According to embodiments, a PMD layer, which may include a USG, may be formed below upper and lower pads. Hence, a wire bonding of an upper pad may be more efficiently performed. This may be because the USG serves as a buffer layer during the wire bonding due to its higher mechanical strength as compared to that of a low dielectric layer, thereby attenuating the pressure. According to embodiments, a lower pad may be formed on and/or over pad area by forming a trench having a width larger than that of a metal interconnection. Copper may then be filled in the trench. This may minimize the occurrence of problems that may occur during the wire bonding even if ultra low-k material, which may have a hardness lower than that of the low-k material, or air gap material is used as the insulating layer. According to embodiments, even if a number of metal interconnections is reduced as a semiconductor device becomes more highly integrated, the wire bonding may be efficiently performed.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
a semiconductor substrate including a cell area and a pad area;
a first insulating layer over the semiconductor substrate;
a first interconnection trench formed in the first insulating layer over the cell area and having a first width, and a first pad trench formed in the first insulating layer over the pad area and having a second width wider than the first width;
a first metal interconnection formed in the first interconnection trench and a first pad formed in the first pad trench;
a second insulating layer over the first insulating layer;
a second interconnection trench formed in the second insulating layer configured to expose the first metal interconnection;
a second pad trench over the second insulating layer configured to expose the first pad; and
a second metal interconnection formed in the second interconnection trench and a second pad formed in the second pad trench.

2. The device of claim 1, wherein the second pad trench has position and width substantially identical to a position and width of the first pad trench.

3. The device of claim 1, wherein at least one of the first and second insulating layers comprises a low dielectric layer and an oxide layer in a stacked formation.

4. The device of claim 3, wherein the low dielectric layer comprises at least one of SiOC:H, HSQ, MSQ, and P-MSQ.

5. The device of claim 1, comprising a barrier layer formed over the first insulating layer.

6. The device of claim 5, wherein the first metal interconnection and the first pad comprise copper, and wherein the barrier layer is configured to prevent the copper of the first metal interconnection and the first pad from diffusing into the first insulating layer.

7. The device of claim 1, comprising an upper pad formed over the second pad.

8. The device of claim 7, wherein the upper pad comprises aluminum.

9. The device of claim 1, comprising a pre-metal dielectric (PMD) layer between the semiconductor substrate and the first insulating layer, wherein the PMD layer comprises at least one of MSQ (methyl silsesquioxane), HSQ (Hydrogen silsesquioxane), FSQ (Fluorine-doped silicate), and CDO (carbon doped oxide).

10. A method comprising:
forming a first insulating layer over a semiconductor substrate including a cell area and a pad area;
forming a first interconnection trench having a first width in the first insulating layer over the cell area, and forming a first pad trench in the first insulating layer over the pad area, the first pad trench having a second width wider than the first width;
forming a second insulating layer over the first insulating layer;
forming a second interconnection trench in the second insulating layer to expose the first metal interconnection;
forming a second pad trench over the second insulating layer configured to expose the first pad and having a position and width substantially identical to a position and width of the first pad trench; and
forming a second metal interconnection in the second interconnection trench and forming a second pad in the second pad trench.

11. The method of claim 10, wherein forming the first and second insulating layers comprises:
forming a low dielectric layer over the semiconductor substrate; and
forming an oxide layer over the low dielectric layer.

12. The method of claim 11, wherein the low dielectric layer comprises at least one of SiOC:H, HSQ, MSQ, and P-MSQ.

13. The method of claim 10, comprising forming a barrier layer over the first insulating layer including the first metal interconnection.

14. The method of claim 13, wherein the first metal interconnection and the first pad comprise copper, and wherein the barrier layer is configured to prevent the copper of the first metal interconnection and the first pad from diffusing into the first insulating layer.

15. The method of claim 10, wherein the first metal interconnection and the first pad each comprise at least one of Cu, Al, Ti, TiN, Ta, Tan, and TiSiN.

16. The method of claim 10, comprising forming a pre-metal dielectric (PMD) layer over the semiconductor substrate, wherein the PMD layer comprises at least one of MSQ (methyl silsesquioxane), HSQ (Hydrogen silsesquioxane), FSQ (Fluorine-doped silicate), and CDO (carbon doped oxide).

17. The method of claim 10, wherein forming the first metal interconnection and the first pad comprises:
forming a photoresist pattern over the first insulating layer;
forming the first interconnection trench having the first width and the first pad trench, which has the second width larger than the first width, in the first insulating layer by etching the first insulating layer using the photoresist pattern as an etch mask; and
forming a metal layer in the first interconnection trench and the first pad trench.

18. The method of claim 10, comprising forming an upper pad over the second pad.

19. The method of claim 18, wherein the upper pad comprises aluminum.

20. The method of claim 10, wherein the first and second metal interconnections comprise copper.
